(19) United States
(12) Patent Application Publication
(10) Pub. No.: US 2007/0057314 A1
(43) Pub. Date: Mar. 15, 2007

(54) Integrated circuit device and electronic instrument

(75) Inventors: Kanji Natori, Fujimi-machi (JP); Kimihiro Maemura, Hara-mura (JP); Tomo Takaso, Chino-shi (JP); Kunio Watanabe, Sakata-shi (JP); Masahiro Hayashi, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/515,909

(22) Filed: Sep. 6, 2006

(30) Foreign Application Priority Data
Sep. 9, 2005 (JP) 2005-262388

(51) Int. Cl. H01L 29/788

(52) U.S. Cl. 257/315

(57) ABSTRACT

A programmable ROM block provided in an integrated circuit device includes a memory cell having a single-layer-gate structure in which a floating gate used in common as gates of a write/read transistor and an erase transistor is opposite to a control gate formed of an impurity layer through an insulating layer. The memory cell the cell was backward has a triple-well structure including a shallow well of a first conductivity type formed on a deep well of a second conductivity type, a ring-shaped shallow well of the second conductivity type which encloses the shallow well of the first conductivity type, and top impurity regions formed in the shallow well of the first conductivity type and the ring-shaped shallow well of the second conductivity type.

Japanese Patent Application No. 2005-262388 filed on Sep. 9, 2005, is hereby incorporated by reference in its entirety.

### BACKGROUND OF THE INVENTION

The present invention relates to an integrated circuit device and an electronic instrument.

A display driver (LCD driver) is known as an integrated circuit device which drives a display panel such as a liquid crystal panel. The display driver is required to have a reduced chip size in order to reduce cost.

On the other hand, a display panel incorporated in a portable telephone or the like has approximately the same size. Accordingly, when reducing the chip size by merely shrinking the integrated circuit device (display driver) using a microfabrication technology, it becomes difficult to mount the integrated circuit device.

When the user manufactures a display device by mounting a display driver on a liquid crystal panel, various adjustments are necessary for the display driver. For example, it is necessary to adjust the display driver conforming to the panel specification (e.g. amorphous TFT, low-temperature polysilicon TFT, QCIF, QVGA, or VGA) or drive conditions, or to adjust the display driver so that the display characteristics do not vary depending on the panel. It is also necessary for the IC manufacturer to adjust the oscillation frequency or the output voltage or to switch to a redundant memory during IC inspection.

In related-art technology, the user adjusts the display driver using an external electrically erasable programmable read only memory (E²PROM) or an external trimmer resistor (variable resistor). The IC manufacturer switches to a redundant memory by blowing a fuse element provided in the integrated circuit device.

It is troublesome for the user to provide external parts, and a trimmer resistor is expensive, has a large size, and easily breaks. It is also troublesome for the IC manufacturer to blow a fuse element and then verify whether the integrated circuit device operates normally.

JP-A-63-166274 proposes a nonvolatile memory device which can be simply manufactured at low cost in comparison with a stacked-gate nonvolatile memory device which requires a two-layer gate. In this nonvolatile memory device, a control gate is formed of an N-type impurity region in a semiconductor layer, and a floating gate electrode is formed of a single-layer conductive layer such as a polysilicon layer (hereinafter may be called “single-layer-gate nonvolatile memory device”). The single-layer-gate nonvolatile memory device can be manufactured using a CMOS transistor process, since it is unnecessary to stack the gate electrodes.

### SUMMARY

According to one aspect of the invention, there is provided an integrated circuit device comprising:

a programmable ROM block including a plurality of memory cells, each of the memory cells including:

a write/read transistor and an erase transistor formed on a semiconductor substrate;

a floating gate which is used in common as gates of the write/read transistor and the erase transistor; and

a control gate which is formed in the semiconductor substrate and formed of an impurity region provided at a position opposite to the floating gate through an insulating layer;

when the semiconductor substrate is a first conductivity type, each of the memory cells having a triple-well structure formed by a deep well of a second conductivity type formed in the semiconductor substrate, a shallow well of the first conductivity type formed in the deep well of the second conductivity type, a ring-shaped shallow well of the second conductivity type which encloses the shallow well of the first conductivity type on the deep well of the second conductivity type, and top impurity regions formed in the shallow well of the first conductivity type and the ring-shaped shallow well of the second conductivity type; and

the erase transistor being formed in the ring-shaped shallow well of the second conductivity type, and the control gate and the write/read transistor being formed in the shallow well of the first conductivity type.

### BRIEF DESCRIPTION OF THE SEVERAL VIEWS OF THE DRAWING

FIG. 1 is a view illustrating a configuration example of an integrated circuit device according to one embodiment of the invention.

FIG. 2 is a view illustrating examples of various types of display drivers and circuit blocks provided in the display drivers.

FIGS. 3A and 3B are views illustrating planar layout examples of an integrated circuit device according to one embodiment of the invention.

FIGS. 4A and 4B are views illustrating examples of a cross-sectional view of an integrated circuit device.

FIG. 5 is a block diagram illustrating the relationship among a programmable ROM, a logic circuit, and a grayscale voltage generation circuit among the circuit blocks shown in FIG. 3A.

FIGS. 6A, 6B, and 6C are characteristic diagrams illustrating a grayscale voltage adjusted using the circuits in FIG. 5.

FIG. 7 is a block diagram of a configuration example of a display device including an electro-optical device.

FIG. 8 is a view illustrating a layout of a programmable ROM block in an integrated circuit device.

FIG. 9 is a view illustrating a layout of a comparative example of FIG. 8.

FIG. 10 is a plan view of a single-layer-gate memory cell disposed in a programmable ROM.

FIG. 11 is an equivalent circuit diagram of the memory cell shown in FIG. 10.

FIG. 12 is a cross-sectional view along the line A-A′ in FIG. 10, illustrating the principle of programming (writing) data into a memory cell.

FIG. 13 is a view illustrative of a change in threshold value of a write/read transistor after programming.

FIG. 14 is a cross-sectional view along the line B-B′ in FIG. 10, illustrating the principle of erasing data in a memory cell.

FIG. 15 is a view illustrative of a change in threshold value of a write/read transistor after erasing.

FIG. 16 is a cross-sectional view along the line A-A′ in FIG. 10, illustrating the principle of reading data from a memory cell in a written state.

FIG. 17 is a cross-sectional view along the line A-A′ in FIG. 10, illustrating the principle of reading data from a memory cell in an erased state.

FIG. 18 is a plan view of a memory cell array block of a programmable ROM.

FIG. 19 is a plan view of two adjacent memory cells.

FIG. 20 is a cross-sectional view along the line C-C′ in FIG. 19.

FIG. 21 is a view illustrating a modification of FIG. 20.

FIG. 22 is a block diagram of a programmable ROM.

FIG. 23 is a view illustrating a planar layout of the entire programmable ROM.

FIGS. 24A and 24B are views illustrating configuration examples of an electronic instrument.

### DETAILED DESCRIPTION OF THE EMBODIMENT

The invention has been achieved in view of the above-described technical problems. An objective of the invention is to provide an integrated circuit device including a programmable ROM having a novel structure which makes it unnecessary to provide external parts and fuse elements and stores adjustment data mainly set by the user, and an electronic instrument including the integrated circuit device.

According to one embodiment of the invention, there is provided an integrated circuit device comprising:

a programmable ROM block including a plurality of memory cells, each of the memory cells including:

a write/read transistor and an erase transistor formed on a semiconductor substrate;

a floating gate which is used in common as gates of the write/read transistor and the erase transistor; and

a control gate which is formed in the semiconductor substrate and formed of an impurity region provided at a position opposite to the floating gate through an insulating layer; when the semiconductor substrate is a first conductivity type, each of the memory cells having a triple-well structure formed by a deep well of a second conductivity type formed in the semiconductor substrate, a shallow well of the first conductivity type formed in the deep well of the second conductivity type, a ring-shaped shallow well of the second conductivity type which encloses the shallow well of the first conductivity type on the deep well of the second conductivity type, and top impurity regions formed in the shallow well of the first conductivity type and the ring-shaped shallow well of the second conductivity type; and

the erase transistor being formed in the ring-shaped shallow well of the second conductivity type, and the control gate and the write/read transistor being formed in the shallow well of the first conductivity type.

The “single-layer-gate” structure according to this embodiment using only the floating gate differs from the related-art structure in that data is written and erased using MOS transistors of different channel conductivity types. As a result, tolerance to an erase voltage can be increased in comparison with the case of erasing data at the same location as the write region. Moreover, the memory cell is formed using a triple-well structure. In particular, the shallow well of the first conductivity type can be electrically separated from the semiconductor substrate by enclosing the shallow well of the first conductivity type, in which the write/read transistor and the control gate are formed, with the ring-shaped shallow well of the second conductivity type in which the erase transistor is formed, and disposing the deep well of the second conductivity type in the lower layer of the shallow well of the first conductivity type and the ring-shaped shallow well of the second conductivity type, whereby the shallow well of the first conductivity type and the semiconductor substrate can be set at different potentials.

In the integrated circuit device according to this embodiment, the shallow well of the first conductivity type may be separated from the ring-shaped shallow well of the second conductivity type, and the deep well of the second conductivity type may be formed between the shallow well of the first conductivity type and the ring-shaped shallow well of the second conductivity type.

A voltage withstand structure can be formed by separating the ring-shaped shallow well of the second conductivity type, in which the erase transistor driven at a relatively high voltage is formed, from the shallow well of the first conductivity type. Since the deep well of the second conductivity type is formed in the space between the ring-shaped shallow well of the second conductivity type and the shallow well of the first conductivity type, even if an interconnect which may serve as the gate of a parasitic transistor extends over the space, the parasitic transistor is not turned ON, whereby the potential of the space is prevented from being reversed.

The integrated circuit device according to this embodiment may further comprise: a transfer gate including a transistor of the first conductivity type and a transistor of the second conductivity type between the write/read transistor and a bitline. The transistor of the second conductivity type may be formed in the shallow well of the first conductivity type.

The ring-shaped shallow well of the second conductivity type may include two long side regions, the erase transistor may be formed in one of the two long side regions, a beltlike shallow well of the second conductivity type may be formed adjacent to the other of the two long side regions, and the transistor of the first conductivity type may be formed in the beltlike shallow well of the second conductivity type.

When the withstand voltage is insufficient, the other of the two long side regions may be separated from the beltlike shallow well of the second conductivity type. In this case, a ring-shaped deep well of the first conductivity type may be formed in a region around the ring-shaped shallow well of the second conductivity type and the beltlike shallow well of the second conductivity type. It is preferable to form an impurity ring of the first conductivity type in a top layer in a region in which the ring-shaped deep well of the first conductivity type is formed. Therefore, even if an interconnect which may serve as the gate of a parasitic transistor extends over the space between the other of the two long side regions and the beltlike shallow well of the second conductivity type, the parasitic transistor is not turned ON, whereby the potential of the space is prevented from being reversed.

A ring-shaped shallow well of the first conductivity type may be formed in a region which encloses the beltlike shallow well of the second conductivity type instead of forming the ring-shaped deep well of the first conductivity type. In order to ensure a sufficient withstand voltage, the ring-shaped shallow well of the first conductivity type may be separated from the other of the two long side regions. In this case, it is preferable to form an impurity ring of the first conductivity type in a top layer of the ring-shaped shallow well of the first conductivity type.

In the integrated circuit device according to this embodiment, it is preferable that a first metal layer or a lower interconnect layer not formed to extend over the impurity ring of the first conductivity type. This aims at preventing the potential of the space from being reversed.

In the integrated circuit device according to this embodiment, a memory cell array block in which the memory cells are arranged may be divided into first and second regions on either side of a center region, and may include two wordline drivers which respectively drive wordlines of the memory cells disposed in the first and second regions, and two control gate drivers which respectively drive control gates of the memory cells disposed in the first and second regions.

This reduces the lengths of the wordline and the control gate by half to prevent a signal delay, and allows the wordline and the control gate to be driven by each driver along the minimum path.

In the integrated circuit device according to this embodiment,

the memory cell array block may include a plurality of column blocks divided in a direction in which the wordlines extend; each of the wordlines may be hierarchized into a main-wordline and a plurality of sub-wordlines subordinate to the main-wordline, and each of the sub-wordlines may be disposed in units of the column blocks;

each of the two wordline drivers may be a main-wordline driver; and

each of the column blocks may include a memory cell region and a sub-wordline decoder region divided in a direction in which the wordlines extend, and a sub-wordline decoder which selectively drives one of the sub-wordlines subordinate to the main-wordline based on logic of the main-wordline may be disposed in the sub-wordline decoder region.

This allows a hierarchical drive of the wordlines.

In the integrated circuit device according to this embodiment, the memory cell region and the sub-wordline decoder region may be formed in a common well region formed on the semiconductor substrate. This makes it unnecessary to provide separate wells, whereby the area of the memory cell array block can be reduced.

In this case, transistors forming the sub-wordline decoder disposed in the sub-wordline decoder region may be formed in the shallow well of the first conductivity type and the beltlike shallow well of the second conductivity type.

In the integrated circuit device according to this embodiment, the first conductivity type may be a P-type, and the second conductivity type may be an N-type. Note that the first conductivity type may be an N-type, and the second conductivity type may be a P-type.

Another embodiment of the invention defines an electronic instrument comprising:

the above integrated circuit device; and

a display panel driven by the integrated circuit device.

Preferred embodiments of the invention are described below in detail. Note that the embodiments described hereunder do not in any way limit the scope of the invention defined by the claims laid out herein. Note that all elements of the embodiments described below should not necessarily be taken as essential requirements for the invention.

1. Configuration of Integrated Circuit Device

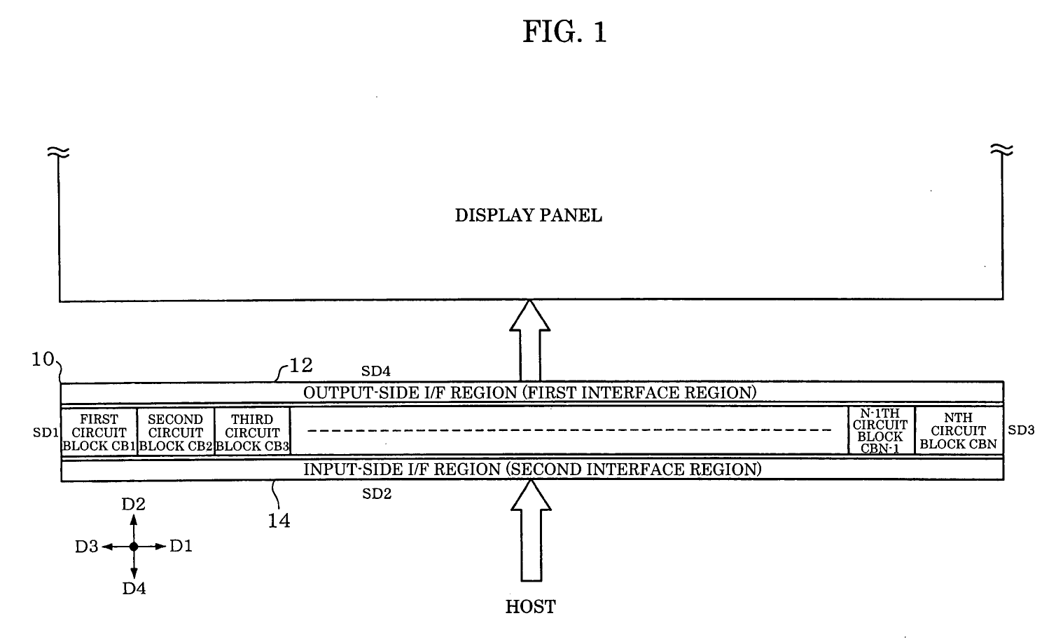

FIG. 1 illustrates a configuration example of an integrated circuit device 10 according to this embodiment. In this embodiment, the direction from a first side SD1 (short side) of the integrated circuit device 10 toward a third side SD3 opposite to the first side SD1 is defined as a first direction D1, and the direction opposite to the first direction D1 is defined as a third direction D3. The direction from a second side SD2 (long side) of the integrated circuit device 10 toward a fourth side SD4 opposite to the second side SD2 is defined as a second direction D2, and the direction opposite to the second direction D2 is defined as a fourth direction D4. In FIG. 1, the left side of the integrated circuit device 10 is the first side SD1, and the right side is the third side SD3. Note that the left side may be the third side SD3, and the right side may be the first side SD1.

As shown in FIG. 1, the integrated circuit device 10 according to this embodiment includes first to Nth circuit blocks CB1 to CBN (N is an integer of two or more) disposed along the direction D1 (along the long side of the integrated circuit device 10). In this embodiment, the circuit blocks CB1 to CBN are arranged along the direction D1.

The integrated circuit device 10 also includes an output-side I/F region 12 (first interface region in a broad sense) provided along the side SD4 on the direction D2 side of the first to Nth circuit blocks CB1 to CBN. The integrated circuit device 10 also includes an input-side I/F region 14 (second interface region in a broad sense) provided along the side SD2 on the direction D4 side of the first to Nth circuit blocks CB1 to CBN.

The first to Nth circuit blocks CB1 to CBN may include at least two (or three) different circuit blocks (circuit blocks having different functions). In this embodiment in which the integrated circuit device 10 is a display driver, a programmable ROM block and a circuit block which is the destination of data from the programmable ROM block, such as a logic circuit block (gate array block) or a power supply circuit block, are indispensable.

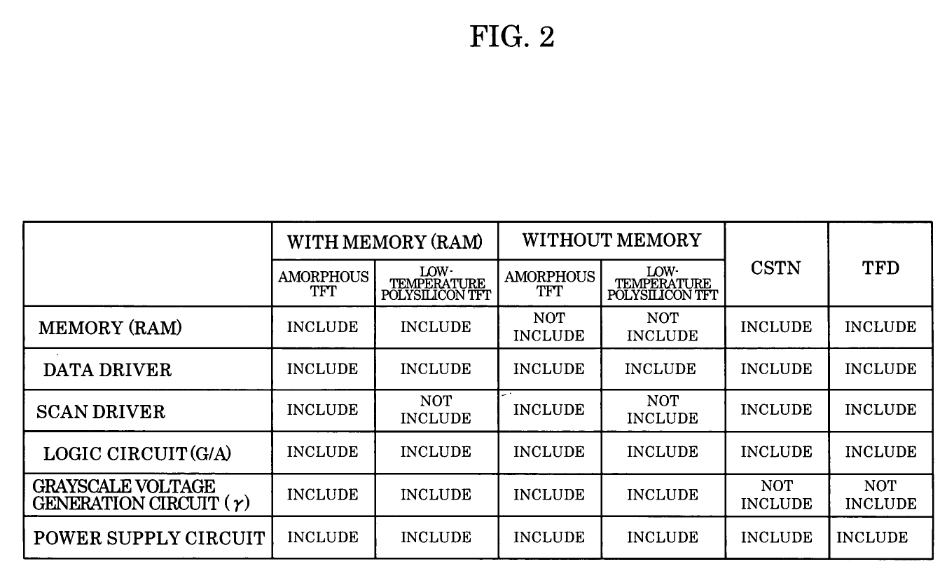

FIG. 2 illustrates examples of various types of display drivers and circuit blocks provided in the display drivers.

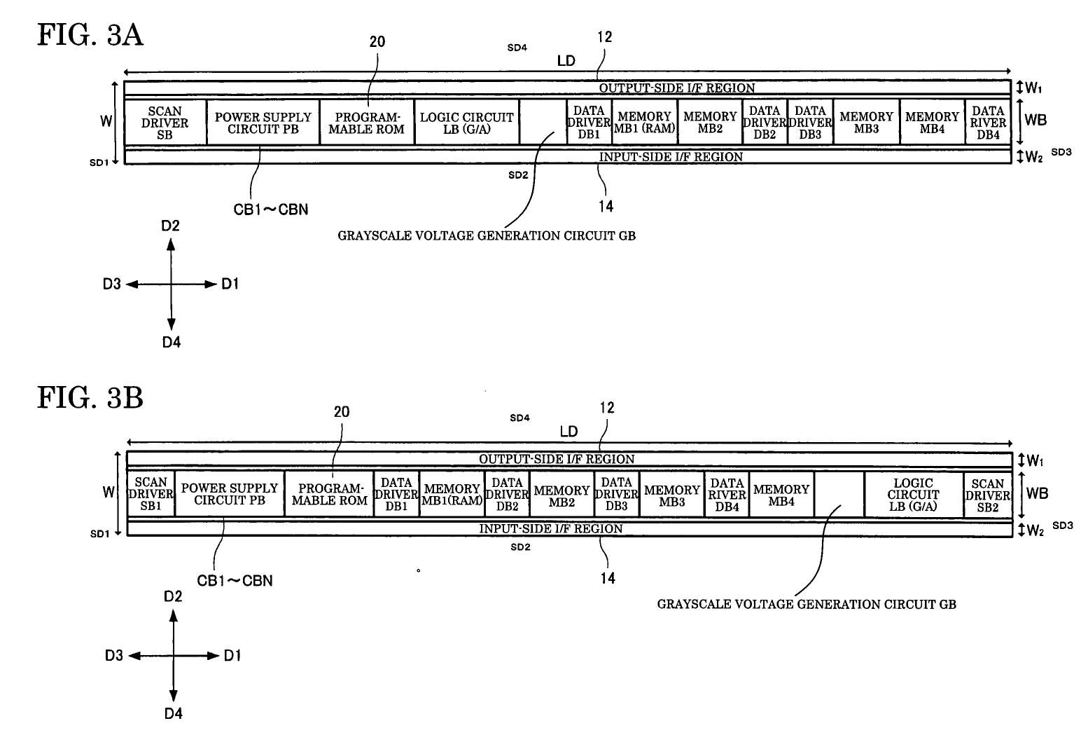

FIGS. 3A and 3B illustrate examples of the planar layout of the integrated circuit device 10 (display driver) according to this embodiment. FIGS. 3A and 3B illustrate examples of an amorphous TFT panel display driver including a memory. FIG. 3A aims at a QCIF 32-grayscale display driver, and FIG. 3B aims at a QVGA 64-grayscale display driver.

In FIG. 3A, a programmable ROM 20 is provided between a power supply circuit PB and a logic circuit LB. In other words, the programmable ROM 20 is adjacent to the blocks of the power supply circuit PB and the logic circuit LB along the direction D1.

In FIG. 3B, the programmable ROM 20 is adjacent to the power supply circuit PB block along the direction D1.

This is because the power supply circuit PB and/or the logic circuit LB is the main destination of data read from the programmable ROM 20. Specifically, data from the programmable ROM 20 can be supplied to the power supply circuit PB and/or the logic circuit LB along a short path. The data read from the programmable ROM 20 is described later.

In FIGS. 3A and 3B, the circuit blocks CB1 to CBN include memory blocks MB1 to MB4 which store display data, data driver blocks DB1 to DB4 disposed adjacent to each memory, a grayscale voltage generation circuit block GB, and one or two scan driver blocks SB (or SB1 and SB2) in addition to the above three blocks.

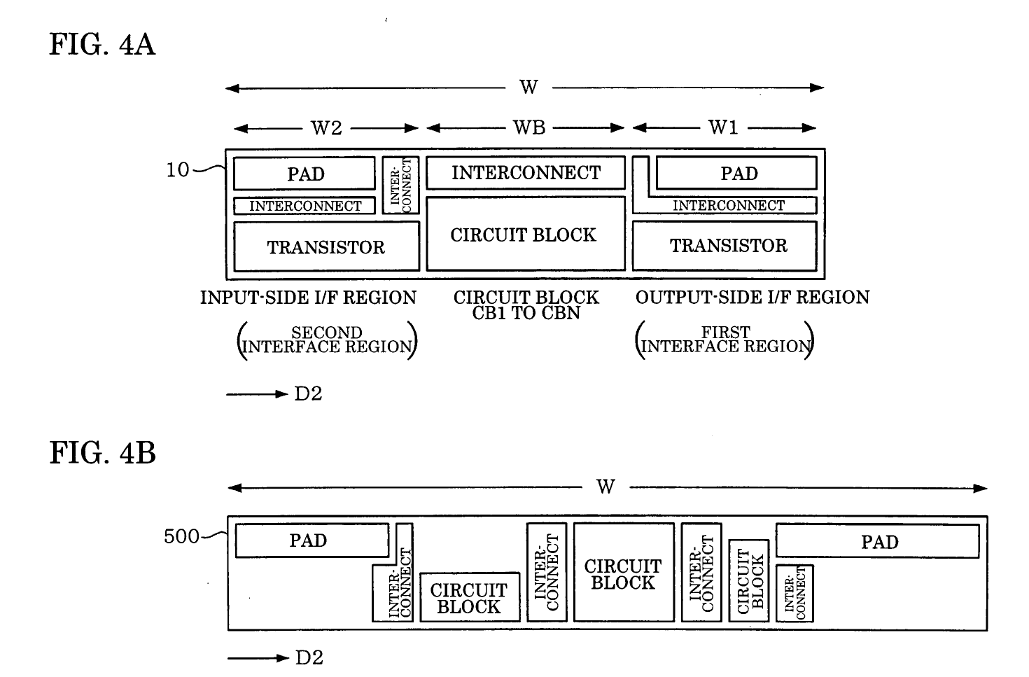

FIG. 4A illustrates an example of a cross-sectional view of the integrated circuit device 10 according to this embodiment along the direction D2. W1, WB, and W2 respectively indicate the widths of the output-side I/F region 12, the circuit blocks CB1 to CBN, and the input-side I/F region 14 in the direction D2. W indicates the width of the integrated circuit device 10 in the direction D2.

In this embodiment, as shown in FIG. 4A, a configuration can be achieved in which another circuit block is not provided between the circuit blocks CB1 to CBN and the output-side and input-side I/F regions 12 and 14 along the direction D2. Therefore, the relationship W1+WB+W2≦W<W1+2×WB+W2 is satisfied, whereby a narrow integrated circuit device can be realized. In more detail, the width W in the direction D2 may be set at W<2 mm. More specifically, the width W in the direction D2 may be set at W<1.5 mm. It is preferable that W>0.9 mm taking inspection and mounting of the chip into consideration. The length LD (see FIGS. 3A and 3B) in the long side direction may be set at 15 mm<LD<27 mm. A chip shape ratio SP=LD/W may be set at SP>10. More specifically, the chip shape ratio SP may be set at SP>12.

FIG. 4B illustrates a comparative example in which two or more circuit blocks are disposed along the direction D2. A wiring region is formed between the circuit blocks or between the circuit block and the I/F region in the direction D2. Therefore, since the width W of an integrated circuit device 500 in the direction D2 (short side direction) is increased, a narrow chip cannot be realized. Therefore, even if the chip is shrunk by using a microfabrication technology, the length LD in the direction D1 (long side direction) is decreased, whereby the output pitch becomes narrow. As a result, it becomes difficult to mount the integrated circuit device.

In this embodiment, since the circuit blocks CB1 to CBN are disposed along the direction D1, it is possible to easily deal with a change in the product specification and the like. Specifically, since products of various specifications can be designed using a common platform, the design efficiency can be improved.

2. Data of Programmable ROM

2.1. Grayscale Voltage Data

In the integrated circuit device according to this embodiment, data stored in the programmable ROM 20 may be adjustment data for adjusting a grayscale voltage. The grayscale voltage generation circuit (gamma correction circuit) generates the grayscale voltage based on the adjustment data stored in the programmable ROM 20. The operation of the grayscale voltage generation circuit (gamma correction circuit) is described below.

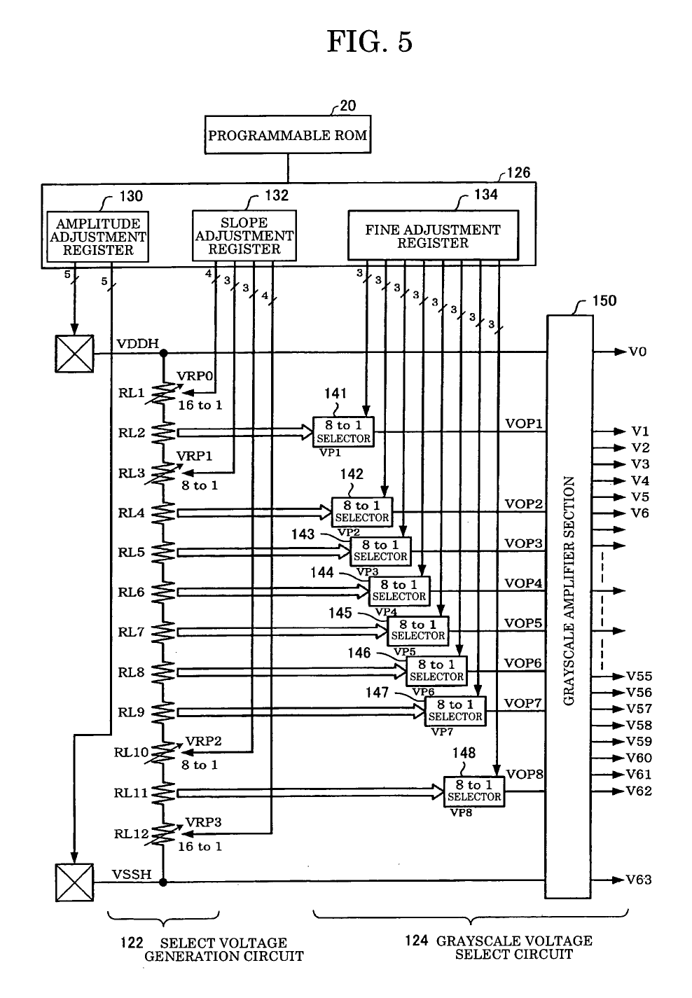

FIG. 5 illustrates the programmable ROM 20, the logic circuit LB, and the grayscale voltage generation circuit (gamma correction circuit) GB among the circuit blocks shown in FIG. 3A.

The adjustment data for adjusting the grayscale voltage is input to the programmable ROM 20 by the user (display device manufacturer), for example. An adjustment register 126 is provided in the logic circuit LB. Various types of setting data which can adjust the grayscale voltage may be set in the adjustment register 126. The setting data is output by reading the adjustment data stored in the programmable ROM 20 into the adjustment register 126. The setting data read from the adjustment register 126 is supplied to the grayscale voltage generation circuit GB.

The grayscale voltage generation circuit GB includes a select voltage generation circuit 122 and a grayscale voltage select circuit 124. The select voltage generation circuit 122 (voltage divider circuit) outputs select voltages based on high-voltage power supply voltages VDDH and VSSH generated by the power supply circuit PB. In more detail, the select voltage generation circuit 122 includes a ladder resistor circuit including a plurality of resistor elements connected in series. The select voltage generation circuit 122 outputs voltages obtained by dividing the power supply voltages VDDH and VSSH using the ladder resistor circuit as the select voltages. When the number of grayscales is 64, the grayscale voltage select circuit 124 selects 64 voltages from the select voltages based on grayscale characteristic setting data supplied from the adjustment register 126, and outputs the selected voltages as grayscale voltages V0 to V63. This allows generation of grayscale voltages with grayscale characteristics (gamma correction characteristics) optimum for the display panel.

The adjustment register 126 may include an amplitude adjustment register 130, a slope adjustment register 132, and a fine adjustment register 134. The grayscale characteristic data is set in the amplitude adjustment register 130, the slope adjustment register 132, and the fine adjustment register 134.

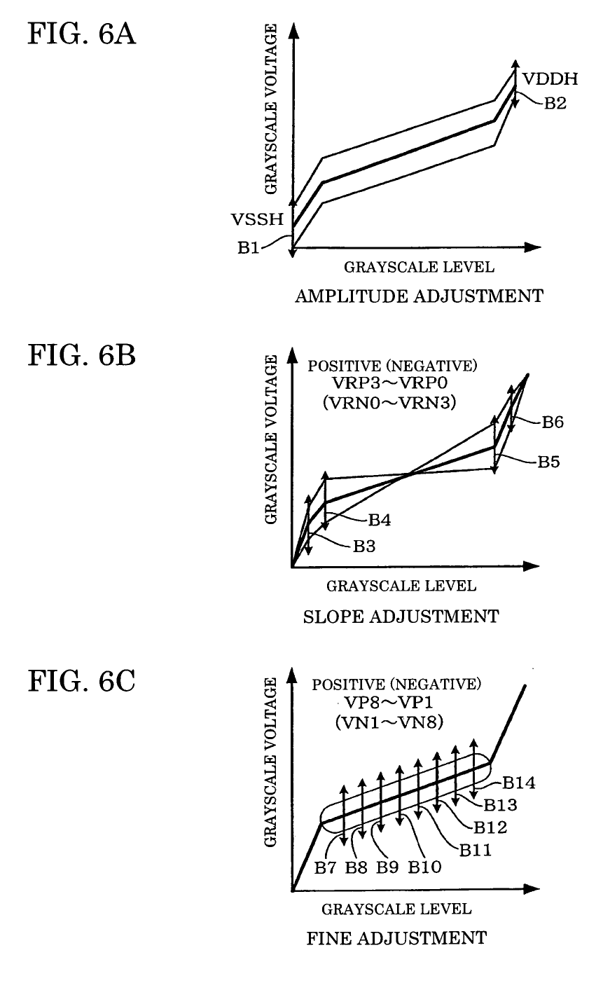

For example, the levels of the power supply voltages VDDH and VSSH are changed, as indicated by B1 and B2 in FIG. 6A, by reading the 5-bit setting data stored in the programmable ROM 20 into the amplitude adjustment register 130, whereby the amplitude of the grayscale voltage can be adjusted.

The grayscale voltage is changed at four points of the grayscale level, as indicated by B3 to B6 in FIG. 6B, by reading the setting data stored in the programmable ROM 20 into the slope adjustment register 132, whereby the slope of the grayscale characteristics can be adjusted. Specifically, the resistances of resistor elements RL1, RL3, RL10, and RL12 forming the resistance ladder are changed based on 4-bit setting data VRP0 to VRP3 set in the slope adjustment register 132, whereby the slope can be adjusted as indicated by B3.

The grayscale voltage is changed at eight points of the grayscale level, as indicated by B7 to B14 in FIG. 6C, by reading the setting data stored in the programmable ROM 20 into the fine adjustment register 134, whereby the grayscale characteristics can be finely adjusted. Specifically, 8-to-1 selectors 141 to 148 respectively select one of eight taps of each of eight resistor elements RL2, RL4 to RL9, and RL 11 based on 3-bit setting data VP1 to VP8 set in the fine adjustment register 134, and output the voltage of the selected taps as outputs VOP1 to VOP8. This enables fine adjustment as indicated by B7 to B14 in FIG. 6C.

A grayscale amplifier section 150 outputs the grayscale voltages V0 to V63 based on the outputs VOP1 to VOP8 from the 8-to-1 selectors 142 to 148 and the power supply voltages VDDH and VSSH. In more detail, the grayscale amplifier section 150 includes first to eighth impedance conversion circuits (voltage-follower-connected operational amplifiers) to which the outputs VOP1 to VPOP8 are input. The grayscale voltages V1 to V62 are generated by dividing the output voltages of adjacent impedance conversion circuits of the first to eighth impedance conversion circuits using resistors, for example.

The grayscale characteristics (gamma characteristics) optimum for each type of display panel can be obtained by the above-described adjustment, whereby the display quality can be improved. In this embodiment, the adjustment data for obtaining grayscale characteristics (gamma characteristics) optimum for each type of display panel is stored in the programmable ROM 20. Therefore, grayscale characteristics (gamma characteristics) optimum for each type of display panel can be obtained, whereby the display quality can be improved.

In this embodiment, the programmable ROM 20 and the logic circuit block LB are adjacently disposed along the first direction D1. This allows adjustment data signal lines from the programmable ROM 20 to be connected with the logic circuit block LB along a short path, whereby an increase in the chip area due to the wiring region can be prevented.

In this embodiment, the logic circuit block LB and the grayscale voltage generation circuit block GB may be adjacently disposed along the direction D1, as shown in FIG. 3A. This allows signal lines from the logic circuit block LB to be connected with the grayscale voltage generation circuit block GB along a short path, whereby an increase in the chip area due to the wiring region can be prevented.

2.2. Panel Setting Voltage Data

In the integrated circuit device according to this embodiment, the data stored in the programmable ROM 20 may be adjustment data for adjusting a panel voltage. The adjustment data for adjusting the panel voltage may be data for adjusting a voltage applied to a common electrode VCOM, for example.

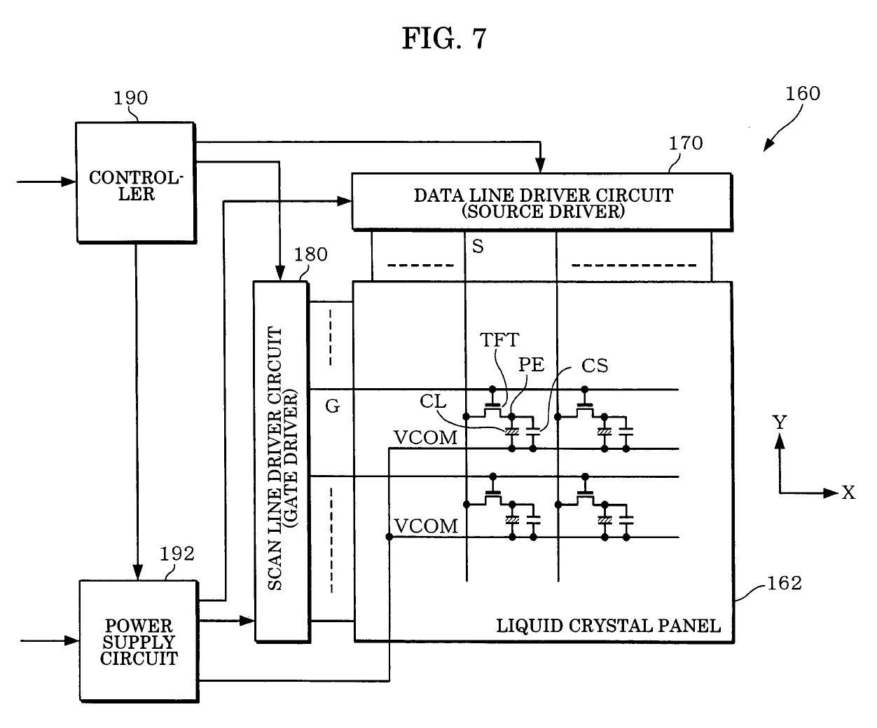

FIG. 7 is a block diagram of a configuration example of a display device including an electro-optical device. The display device shown in FIG. 7 realizes a function of a liquid crystal device. The electro-optical device realizes a function of a liquid crystal panel.

A liquid crystal device 160 (display device in a broad sense) includes a liquid crystal panel (display panel in a broad sense) 162 using a thin film transistor (TFT) as a switching element, a data line driver circuit 170, a scan line driver circuit 180, a controller 190, and a power supply circuit 192.

A gate electrode of the TFT is connected with a scan line G, a source electrode of the TFT is connected with a data line S, and a drain electrode of the TFT is connected with a pixel electrode PE. A liquid crystal capacitor CL (liquid crystal element) and a storage capacitor CS are formed between the pixel electrode PE and a common electrode VCOM opposite to the pixel electrode PE through a liquid crystal element (electro-optical substance in a broad sense). A liquid crystal is sealed between an active matrix substrate, on which the TFT, the pixel electrode PE, and the like are formed, and a common substrate, on which the common electrode VCOM is formed. The transmissivity of the pixel changes corresponding to the voltage applied between the pixel electrode PE and the common electrode VCOM.

In this embodiment, adjustment data for adjusting the voltage applied to the common electrode VCOM may be stored in the programmable ROM 20. The voltage generated by the power supply circuit 192 is adjusted based on the adjustment data, and the adjusted voltage is applied to the common electrode VCOM. The display quality can be improved by setting the adjustment data for each display panel.

In this embodiment, the programmable ROM 20 and the power supply circuit block PB are adjacently disposed along the first direction D1, as shown in FIG. 3A. This allows adjustment data signal lines from the programmable ROM 20 to be connected with the power supply circuit block PB along a short path, whereby an increase in the chip area due to the wiring region can be prevented.

2.3. Other Types of User Setting Information

In the integrated circuit device according to this embodiment, the data stored in the programmable ROM 20 is not limited to the above data. For example, adjustment data for adjusting a given timing may be stored in the programmable ROM 20 as display driver adjustment data. Specifically, various control signals which control the refresh cycle of the memory or the display timing may be generated based on the adjustment data. Adjustment data for adjusting start sequence setting of the integrated circuit device may be stored in the programmable ROM 20 as the display driver adjustment data.

The above adjustment data is programmed by the user. Note that data adjusted by the IC manufacturer during IC manufacture/inspection may also be stored in the programmable ROM 20.

3. Programmable ROM

3.1. Entire Configuration of Programmable ROM

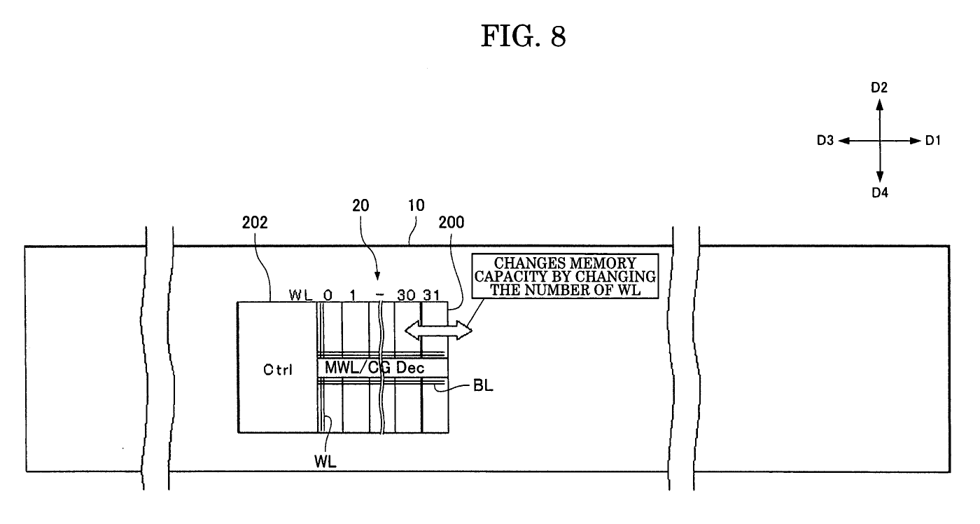

FIG. 8 illustrates the programmable ROM 20 disposed in the integrated circuit device 10. The programmable ROM 20 includes a memory cell array block 200 and a control circuit block 202. The memory cell array block 200 and the control circuit block 202 are adjacently disposed along the direction D1 (long side direction) of the integrated circuit device 10.

A plurality of wordlines WL and a plurality of bitlines BL are provided in the memory cell array block 200. The wordlines WL extend along the direction D2 (short side direction) of the integrated circuit device 10. The bitlines BL extend along the direction D1 (long side direction) of the integrated circuit device 10. The reasons therefor are as follows.

The storage capacity of the programmable ROM 20 can be increased or decreased for each model depending on the user's specification and the like. In this embodiment, the storage capacity is increased or decreased by changing the number of wordlines WL. Specifically, the length of the wordline WL is not changed even if the storage capacity is changed. As a result, the number of memory cells connected with one wordline WL is fixed. The storage capacity of the programmable ROM 20 is increased by increasing the number of wordlines WL. Even if the storage capacity of the programmable ROM 20 is increased, the size of the memory cell array block 200 is not increased in the short side direction (direction D2) of the integrated circuit device 10. Therefore, a narrow shape described with reference to FIG. 1 can be maintained.

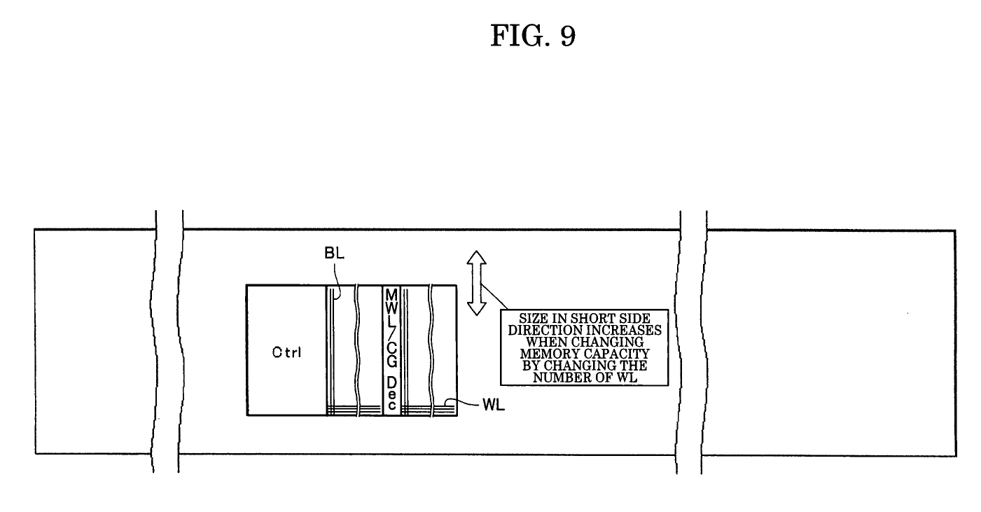

As another reason, even if the storage capacity of the programmable ROM 20 is increased, the size of the control circuit block 202 is not increased in the short side direction (direction D2) of the integrated circuit device 10. Therefore, a narrow shape described with reference to FIG. 1 can be maintained. In FIG. 9 which illustrates a comparative example, the size of the memory cell array block 200 is increased in the short side direction (direction D2) of the integrated circuit device 10 as a result of increasing the storage capacity of the programmable ROM 20. In this case, it is necessary to redesign the circuit of the control circuit block 202. On the other hand, redesign is unnecessary for the layout shown in FIG. 8 according to this embodiment, in which the layout shown in FIG. 9 (comparative example) is rotated by 90°. Therefore, even if the storage capacity of the programmable ROM 20 is increased or decreased, the design efficiency of the control circuit block 202 can be improved.

As yet another reason, since the bitlines BL extend along the direction D1 (long side direction) of the integrated circuit device 10, the control circuit block 202 can be disposed on the extension lines of the bitlines BL. One of the functions of the control circuit block 202 is to detect data read through the bitline BL using a sense amplifier and supply the data to another circuit block. According to the above layout, the data read from the memory cell array block 200 can be supplied to the control circuit block 202 along a short path in comparison with the comparative example shown in FIG. 9.

3.2. Single-layer Gate Memory Cell

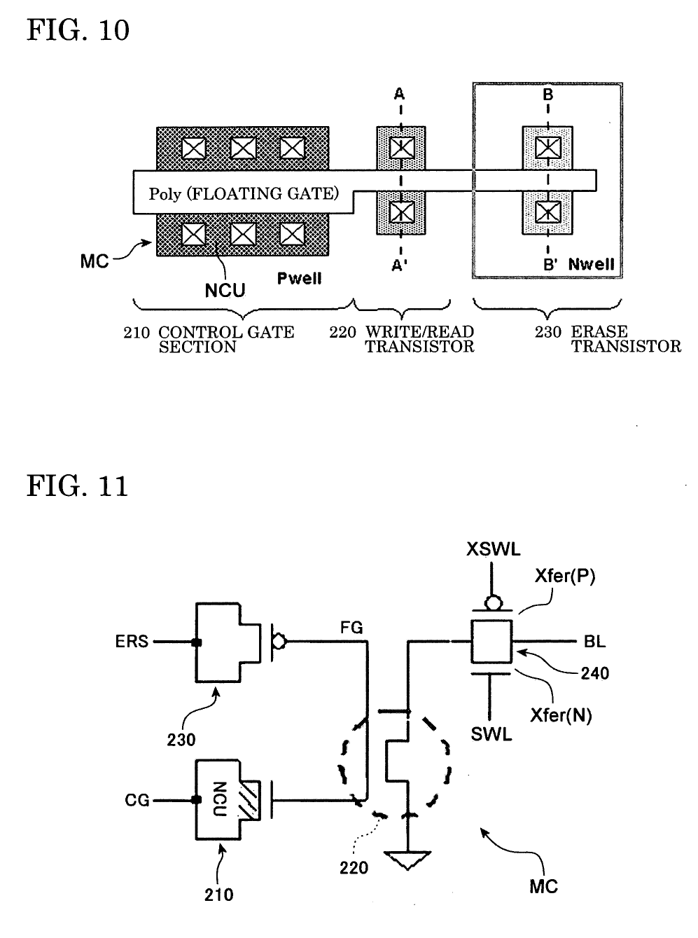

FIG. 10 is a plan view of a single-layer-gate memory cell MC disposed in the memory cell array block 200 shown in FIG. 8. FIG. 11 is an equivalent circuit diagram of the single-layer-gate memory cell MC.

In FIG. 10, the memory cell MC includes a control gate section 210, a write/read transistor 220, and an erase transistor 230. A floating gate FG formed of a polysilicon extends over these regions. As shown in FIG. 11, the memory cell MC includes a transfer gate 240 provided between the drain of the write/read transistor 220 and the bitline BL. The transfer gate 240 connects/disconnects the drain of the write/read transistor 220 and the bitline BL based on the logic of a sub-wordline SWL and the logic of an inversion sub-wordline XSWL. The transfer gate 240 includes a P-type MOS transistor Xfer (P) and an N-type MOS transistor Xfer (N). When the wordline is not hierarchized, the transfer gate 240 is controlled based on the logic of the wordline and the inversion wordline.

The term “single-layer-gate” means that only the floating gate FG is formed of a polysilicon since a control gate CG is formed using an N-type (second conductivity type in a broad sense) impurity layer NCU formed in a P-type well PWEL in a semiconductor substrate (e.g. P-type; first conductivity type in a broad sense). Specifically, the two-layer gate of the control gate CG and the floating gate FG is not entirely formed using a polysilicon. A coupling capacitor is formed by the control gate CG and the floating gate FG opposite to the control gate CG.

The “single-layer-gate” structure according to this embodiment using only the floating gate differs from the related-art structure in that data is written and erased using MOS transistors of different channel conductivity types. An advantage obtained by writing and erasing data using different MOS transistors is as follows. Specifically, data is erased by applying a voltage to a portion with a small capacitive coupling and setting a portion with a large capacitive coupling at 0 V to remove electrons injected into the floating gate through a Fowler-Nordheim (FN) tunneling current. As a related-art single-layer-gate nonvolatile memory device, a nonvolatile memory device is known in which data is written and erased using a single MOS transistor (single portion). The single-layer-gate nonvolatile memory device is designed so that the capacitance of the write region is decreased since it is necessary to increase the capacitance between the control gate and the floating gate electrode in comparison with the capacitance of the write region. Specifically, when erasing data, it is necessary to apply a high erase voltage to a portion with a capacitive coupling.

However, a scaled-down nonvolatile memory device may not sufficiently withstand the voltage applied when erasing data, whereby the MOS transistor may be destroyed. Therefore, in the programmable ROM block according to this embodiment, data is written and erased using different MOS transistors which differ in channel conductivity type. When a P-channel MOS transistor is formed as the MOS transistor for erasing data, this MOS transistor is formed on an N-type well. Therefore, a voltage up to the junction breakdown voltage between the N-type well and the substrate (semiconductor layer) can be applied during erasing. As a result, tolerance to the erase voltage can be increased in comparison with the case of erasing data at the same location as the write region, thereby enabling scaling down and improving reliability.

The integrated circuit device 10 according to this embodiment includes a low voltage (LV) system (e.g. 3 V), a middle voltage (MV) system (e.g. 6 V), and a high voltage (HV) system (e.g. 20 V). The memory cell MC has an MV withstand structure. The write/read transistor 220 and the N-type MOS transistor Xfer (N) are MV N-type MOS transistors, and the erase transistor 230 and the P-type MOS transistor Xfer (P) are MV P-type MOS transistors.

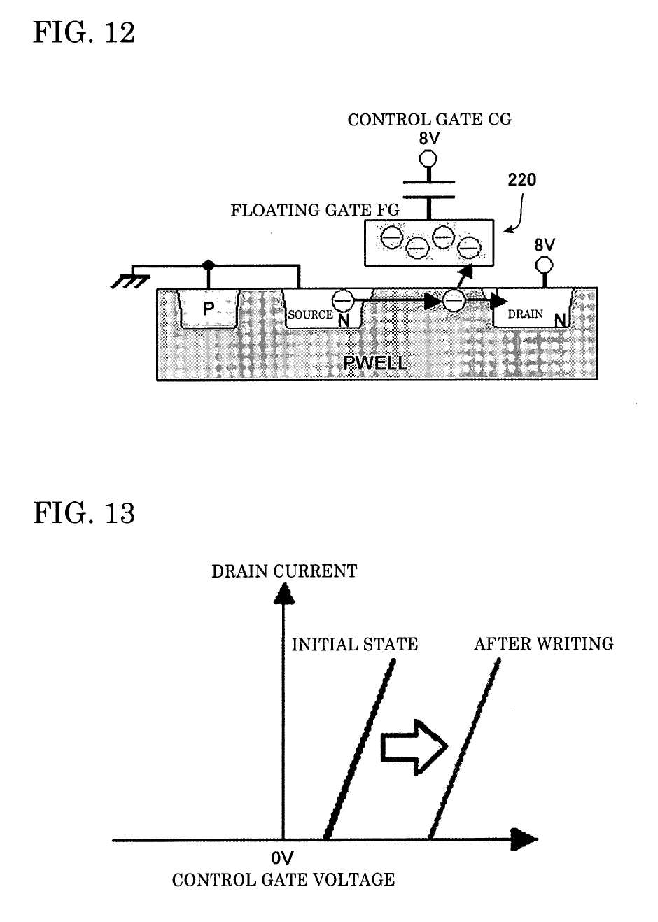

FIG. 12 illustrates the operation of writing (programming) data into the memory cell MC. For example, 8 V is applied to the control gate CC, and 8 V is applied to the drain of the write transistor 220 through the bitline BL and the transfer gate 240. The potentials of the source of the write/read transistor 220 and the P-type well PWEL are 0 V. This causes hot electrons to be generated in the channel of the write/read transistor 220 and drawn into the floating gate of the write/read transistor 220. As a result, the threshold value Vth of the write/read transistor 220 becomes higher than that in the initial state, as shown in FIG. 13.

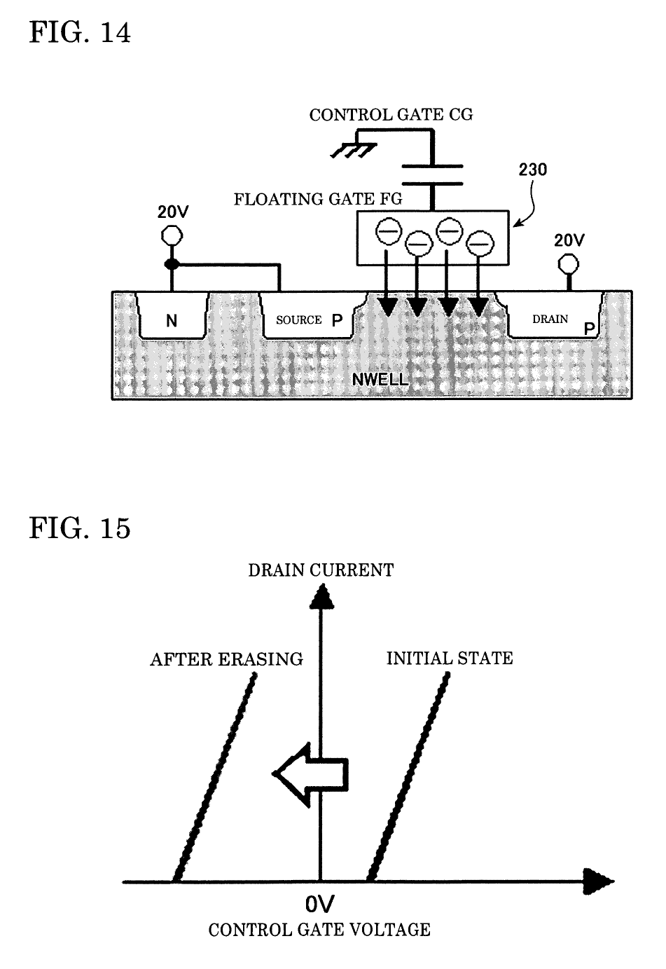

When erasing data, as shown in FIG. 14, 20 V is applied to the drain of the erase transistor 230, and the control gate CG is grounded, for example. The potentials of the source of the erase transistor 230 and the N-type well NWEL are 20 V, for example. This causes a high voltage to be applied between the control gate CG and the N-type well NWEL, whereby electrons in the floating gate FG are drawn into the N-type well NWEL. The data is erased by this FN tunneling current. In this case, the threshold value Vth of the write/read transistor 220 becomes a negative value lower than that in the initial state, as shown in FIG. 15.

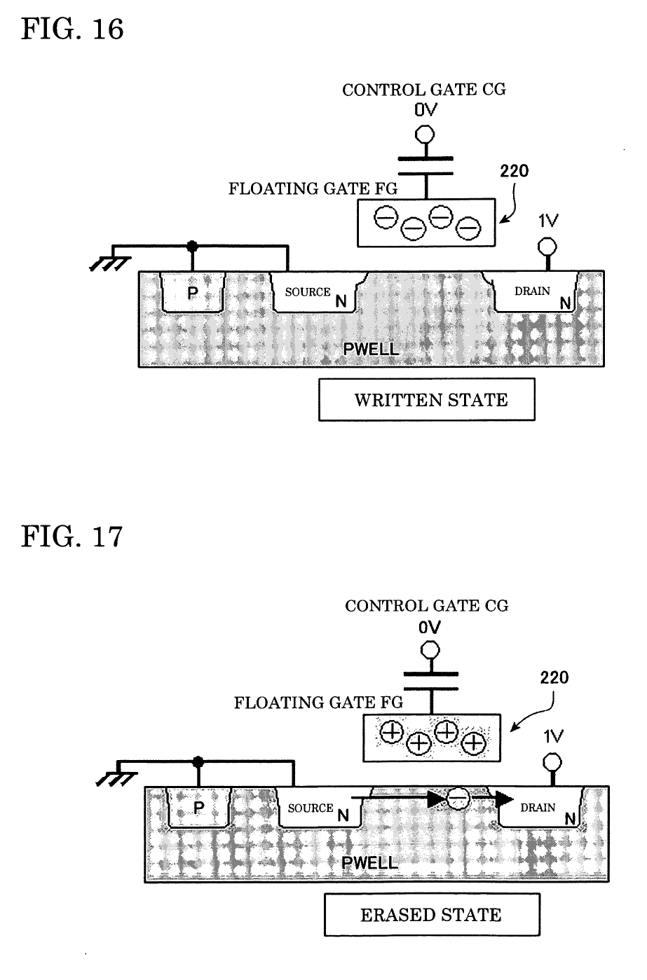

When reading data, as shown in FIGS. 16 and 17, the control gate CG is grounded, and 1 V is applied to the drain of the write/read transistor 220, for example. The potentials of the source of the write/read transistor 220 and the P-type well PWEL are 0 V. In the written state shown in FIG. 16, since the floating gate FG contains excess electrons, current does not flow through the channel. In the erased state shown in FIG. 17, since the floating gate FG contains excess holes, current flows through the channel. The data can be read by detecting the presence or absence of current.

The programmable ROM 20 according to this embodiment is mainly used as a nonvolatile memory in which the user stores the adjustment data instead of a related-art E²PROM or a trimmer resistor, or the IC manufacturer stores the adjustment data during manufacture/inspection, as described above. Therefore, it suffices that data can be rewritten about five times.

3.3. Memory Cell Array Block

3.3.1. Planar Layout

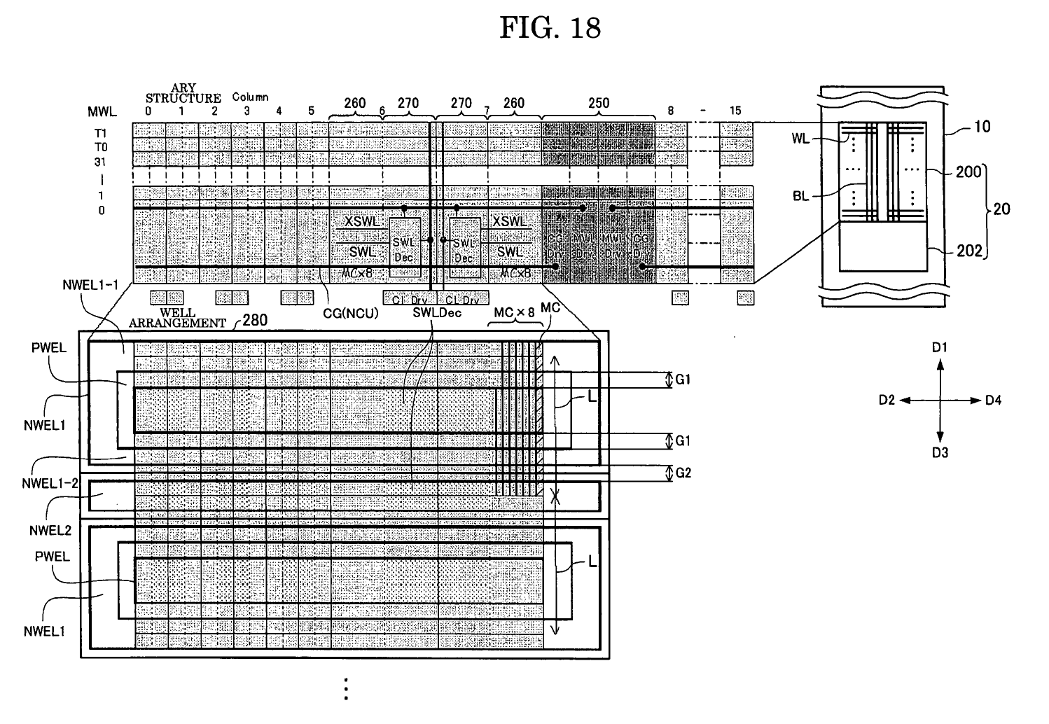

FIG. 18 is an enlarged plan view illustrating the memory cell array block 200 and part of the memory cell array block 200. In the memory cell array block 200, a formation region 250 of a main-wordline driver MWLDrv and a control gate line driver CGDrv is provided at the center in the short side direction (direction D2) of the integrated circuit device 10. The memory cell array block 200 is divided into first and second regions on either side of the formation region 250. In this embodiment, eight column blocks are provided in each of the first and second regions so that sixteen column blocks 0 to 15 are provided in total. Eight memory cells MC are disposed in one column block along the direction D2. In this embodiment, the length W of the short side of the integrated circuit device 10 shown in 3A is 800 μm, and the number of memory cells MC which can be arranged within the length W is determined to be “16 columns×8 memory cells” based on the length of one memory cell MC in the direction D2. The storage capacity of the programmable ROM 20 may be increased or decreased by increasing or decreasing the number of wordlines. The main-wordline driver MWLDrv and the control gate line driver CGDrv are provided for each region formed by dividing the memory cell array block 200 in two regions (i.e. two main-wordline drivers MWLDrv and two control gate line drivers CGDrv are provided in the memory cell array block 200). The main-wordline driver MWLDrv and the control gate line driver CGDrv may be provided on the end of the memory array block 200.

In FIG. 18, the total number of main-wordlines MWL driven by one main-wordline driver MWLDrv is 34. Two of the main-wordlines MWL are test main-wordlines T1 and T0 connected with test-bit memory cells for the IC manufacturer, and the remaining 32 main-wordlines MWL are main-wordlines MWL0 to MWL31 for the user. The control gate line CG (N-type impurity layer NCU shown in FIG. 10) driven by one control gate line driver CGDrv extends in parallel to the main-wordline MWL.

Each of the 16 column blocks 0 to 15 includes a memory cell region 260 and a sub-wordline decoder region 270. A sub-wordline decoder SWLDec connected with each main-wordline MWL is provided in the sub-wordline decoder region 270. A column driver CLDrv is provided in the region of the control circuit block 202 in units of the sub-wordline decoder regions 270. The output line of the column driver CLDrv is connected in common with all the sub-wordline decoders SWLDec disposed in each sub-wordline decoder region 270.

The sub-wordline SWL and the inversion sub-wordline XSWL extend from one sub-wordline decoder SWLDec toward the adjacent memory cell region 260. In one column block, eight memory cells MC connected in common with the sub-wordline SWL and the inversion sub-wordline XSWL are disposed in the memory cell region 260, for example.

In the layout shown in FIG. 18, one sub-wordline decoder SWLDec is selected when one main-wordline MWL is selected by the main-wordline driver MWLDrv and one column block is selected by the column decoder CLDrv. The eight memory cells MC connected with the selected sub-wordline decoder SWLDec are selected, and data is programmed (written) into or read from the selected memory cells.

3.3.2. Well Layout of Memory Cell Region and Sub-wordline Decoder Region

FIG. 18 illustrates a well layout common to the memory cell region 260 and the sub-wordline decoder region 270. Three wells are used to form one memory cell MC in the memory cell region 260. The three wells include a P-type well PWEL (shallow well of the first conductivity type in a broad sense) which extends in the direction (direction D2) along the main-wordline MWL, a ring-shaped N-type well NWEL1 (ring-shaped shallow well of the second conductivity type in a broad sense) which encloses the P-type well PWEL, and a beltlike N-type well NWEL2 (beltlike shallow well of the second conductivity type in a broad sense) which extends in the direction (direction D2) along the main-wordline MWL on the side of the ring-shaped N-type well NWEL1. One of the long side regions of the ring-shaped N-type well NWEL1 is called NWEL1-1, and the other long side region (NWEL2 side) is called NWEL1-2.

One memory cell MC is formed on the three wells (PWEL, NWEL1, and NWEL2) over the length region L of one memory cell shown in FIG. 18. Eight memory cells MC connected in common with one sub-wordline decoder SWLDec are formed in the length region L in each memory cell region 260, as shown in FIG. 18.

In FIG. 18, a P-type impurity ring 280 (impurity ring of the first conductivity type in a broad sense) which encloses the ring-shaped N-type well NWEL1 and the beltlike N-type well NWEL2 is provided. The P-type impurity ring 280 is described later.

In FIG. 18, the above three wells (PWEL, NWEL1, and NWEL2) are also formed in the sub-wordline decoder region 270. Note that transistors forming the sub-wordline decoder SWLDec are formed on the P-type well PWEL and the beltlike N-type well NWEL2 indicated as dot regions in FIG. 18, but are not formed on the ring-shaped N-type well NWEL1.

3.3.3. Planar Layout and Cross-sectional Structure of Memory Cell

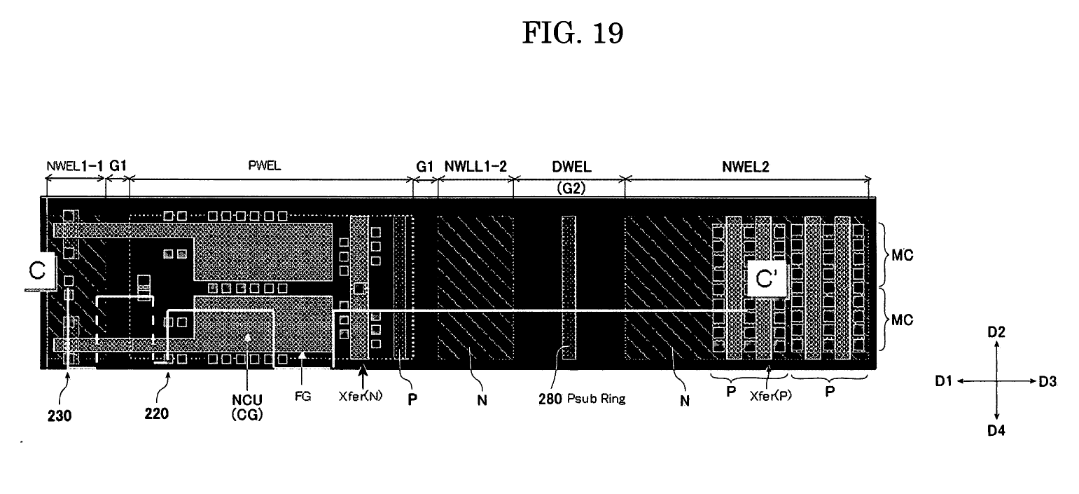

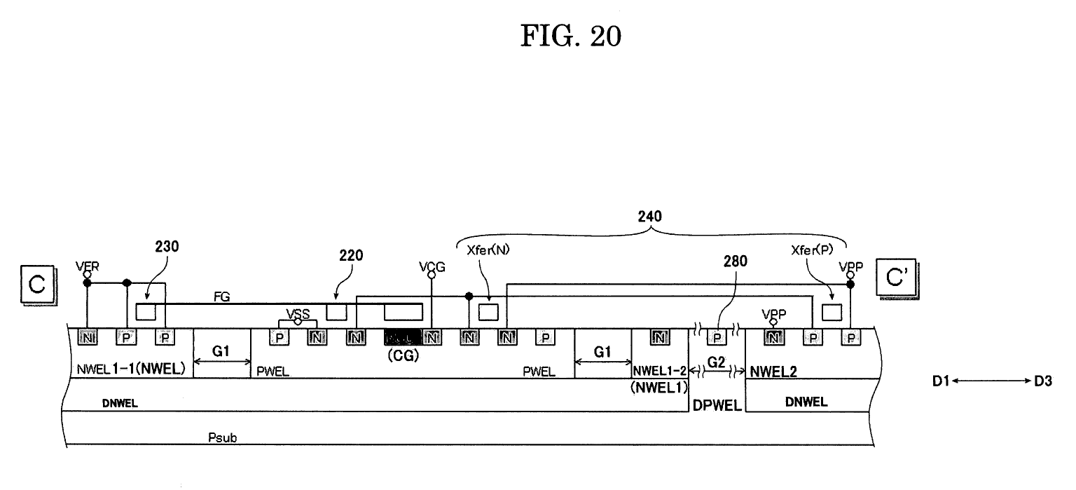

FIG. 19 illustrates a planar layout of two memory cells MC adjacent in FIG. 18. FIG. 20 is a cross-sectional view of one memory cell MC along the line C-C′ in FIG. 19. The cross section along the line C-C′ in FIG. 19 indicated by the broken lines in the direction D2 is omitted in FIG. 20. Note that the dimensions in the direction Dl along the line C-C′ in FIG. 19 do not necessarily coincide with the dimensions in the direction D1 in FIG. 20.

In FIG. 19, two memory cells MC are disposed in a mirror image when viewed from the top side. As shown in FIG. 19, the memory cell MC is formed over the three wells (PWEL, NWEL1, and NWEL2), as described above. As shown in FIG. 20, a deep N-type well DNWEL (deep well of the second conductivity type in a broad sense) is provided in the lower layer of the ring-shaped N-type well NWEL1 inside the outer edge thereof and the lower layer of the beltlike N-type well NWEL2. As shown in FIG. 20, since a P-type or N-type impurity region (top impurity region in a broad sense) is provided in the three wells (PWEL, NWEL1, and NWEL2) on the deep N-type well DNWEL, the memory cell MC according to this embodiment has a triple-well structure. This allows the P-type substrate Psub and the P-type well PWEL to be set at different potentials. Since not only the programmable ROM 20, but also other circuit blocks are formed on the P-type substrate Psub, it is necessary to apply a backgate voltage or the like. Therefore, the potential of the P-type substrate Psub is not necessarily fixed at a ground potential.

As shown in FIGS. 19 and 20, the polysilicon floating gate FG is formed in the upper layer of the long side region NWEL1-1 of the ring-shaped N-type well NWEL1 and the P-type well PWEL through an insulating film (not shown). The floating gate FG functions as a common gate of the write/read transistor 220 formed in the P-type well PWEL and the erase transistor 230 formed in the long side region NWEL1-1 of the ring-shaped N-type well NWEL1. An N-type impurity region NCU is formed in the P-type well PWEL opposite to the floating gate FG through the insulating film. The N-type impurity region NCU is provided with the control gate voltage VCG and functions as the control gate CG.

The N-type MOS transistor Xfer (N) of the transfer gate 240 shown in FIG. 11 is provided in the P-type well PWEL. The P-type MOS transistor Xfer (P) of the transfer gate 240 is provided in the beltlike N-type well NWEL2. As shown in FIG. 19, the gate width is ensured by connecting the P-type MOS transistors Xfer (P) in parallel to provide a drive capability.

The N-type impurity region is provided in the long side region NWEL1-2 of the ring-shaped N-type well NWEL1, but an active element is not provided in the long side region NWEL1-2. The long side region NWEL1-2 is merely connected with the long side region NWEL1-1 to enclose the P-type well PWEL in the shape of a ring. If the long side region NWEL1-2 is not formed, the P-type well PWEL cannot be electrically separated from the P-type substrate Psub, even if the deep N-type well DNWEL is disposed.

In this embodiment, the P-type well PWEL is separated from the ring-shaped N-type well NWEL1 disposed outside the P-type well PWEL in the upper layer of the deep N-type well DNWEL. A space G1 is provided to withstand a voltage of 20 V applied between the ring-shaped N-type well NWEL1, to which 20 V is applied during erasing, and the P-type well PWEL which is set at the potential VSS. In this embodiment, the width of the space G1 is set at 1 μm. Note that the space G1 is unnecessary when it is possible to withstand the voltage applied between the ring-shaped N-type well NWEL1 and the P-type well PWEL. For example, when the design rule is 0.25 μm, the space G1 is unnecessary. When the design rule is 0.18 μm, the space G1 may be provided to ensure the withstand voltage.

A space G2 is also provided between the ring-shaped N-type well NWEL1 and the beltlike N-type well NWEL2. The deep N-type well DNWEL is not disposed in the region of the space G2 in order to electrically separate the ring-shaped N-type well NWEL1 from the beltlike N-type well NWEL2. A deep P-type well DPWEL (ring-shaped deep well of the first conductivity type in a broad sense) is formed in the region of the space G2 instead of the deep N-type well DNWEL. The deep P-type well DPWEL has an impurity concentration higher to some extent than that of the P-type substrate Psb and lower than that of the shallow P-type well PWEL, and is provided to increase the withstand voltage between the ring-shaped N-type well NWEL1 and the beltlike N-type well NWEL2. The deep P-type well DPWEL is disposed in the shape of a ring to enclose the ring-shaped N-type well NWEL1 and the beltlike N-type well NWEL2 in FIG. 18.

In this embodiment, the P-type impurity layer (P-type ring; impurity ring of the first conductivity type in a broad sense) is disposed in the top layer of the space G2 in the shape of a ring when viewed from the top side. The formation region of the P-type ring 280 encloses the ring-shaped N-type well NWEL1 and the beltlike N-type well NWEL2, as shown in FIG. 18.

Even if a metal interconnect which may serve as the gate of a parasitic transistor extends over the space G2, the parasitic transistor is not turned ON due to the P-type ring 280, whereby the potential of the space G2 is prevented from being reversed. In this embodiment, the width of the space G2 is set at 4.5 μm, and the width of the P-type ring 280 positioned at the center of the space G2 is set at 0.5 μm. In this embodiment, a polysilicon layer or a first-layer metal interconnect which may serve as the gate of the parasitic transistor is formed not to extend over the space G2 in order to prevent potential reversal. A second or higher layer metal interconnect may extend over the space G2.

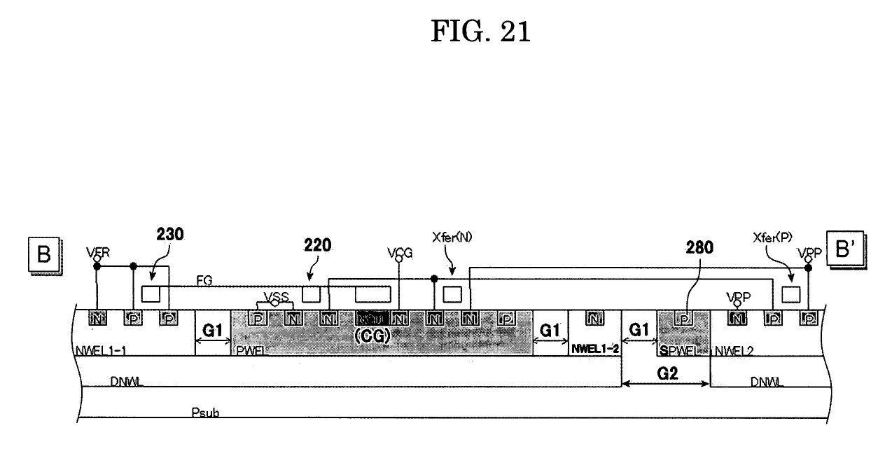

FIG. 21 illustrates a modification of FIG. 20. In FIG. 21, a ring-shaped shallow P-type well SPWEL (ring-shaped shallow well of the first conductivity type in a broad sense) is provided in the space G2 without providing the ring-shaped deep P-type well DPWEL. The P-type ring 280 is formed in the ring-shaped shallow P-type well SPWEL. The space G1 (e.g. 1 μm) between the long side region NWEL1-1 of the ring-shaped N-type well NWEL1 and the shallow P-type well SPWEL is provided in order to withstand a voltage of 20 V for the above-described reason.

3.3.4. Control Circuit Block

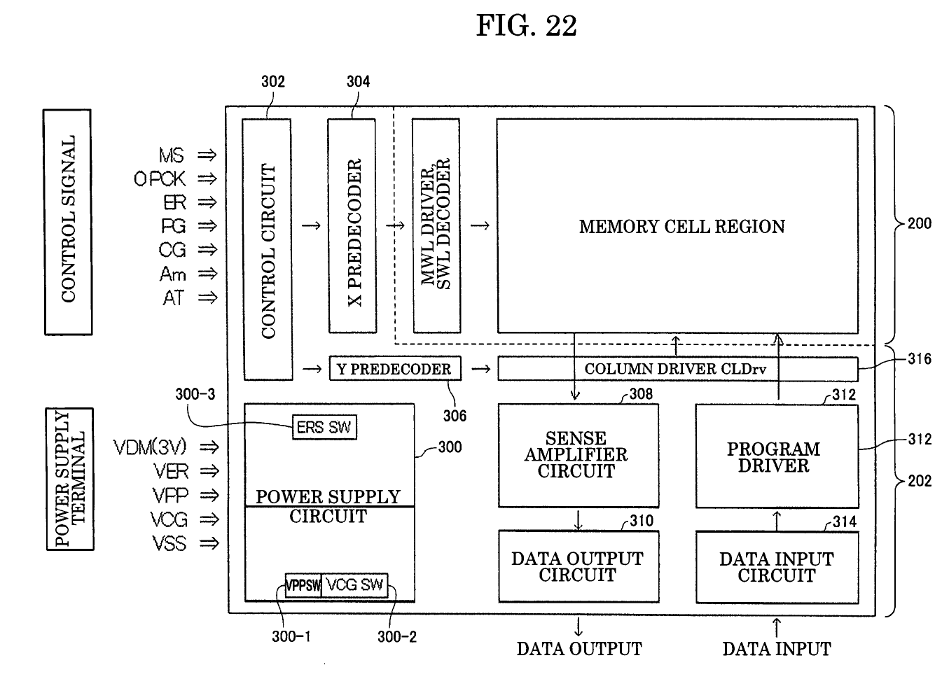

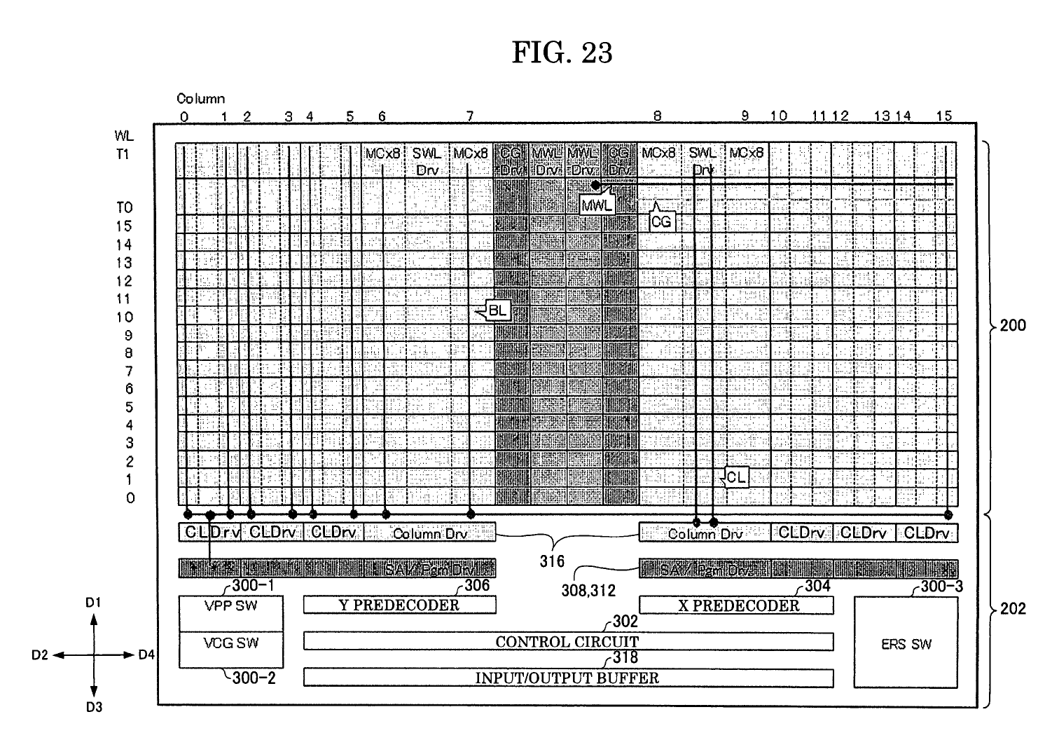

The control circuit block 202 shown in FIG. 8 is described below. FIG. 22 is a block diagram of the control circuit block 202, and FIG. 23 is a layout diagram of the control circuit block 202. The control circuit block 202 is a circuit block for controlling data programming (writing), reading, and erasing of the memory cell MC in the memory cell array block 200. As shown in FIG. 22, the control circuit block 202 includes a power supply circuit 300, a control circuit 302, an X predecoder 304, a Y predecoder 306, a sense amplifier circuit 308, a data output circuit 310, a program driver 312, a data input circuit 314, and the above-described column driver 316 (CLDrv). An input/output buffer 318 shown in FIG. 23 includes the data output circuit 310 and the data input circuit 314 shown in FIG. 22. The power supply circuit 300 includes a VPP switch 300-1, a VCG switch 300-2, and an ERS (erase) switch 300-3.

As shown in FIG. 23, the memory cell array block 200 and the control circuit block 202 are adjacent along the direction D1. Data read from the memory cell array block 200 is output along the direction (direction D1) in which the bitline BL of the memory cell array block 200 extends through the control circuit block 202 and the input/output buffer 318 in the control circuit block 202.

As described with reference to FIGS. 3A and 3B, the programmable ROM 20 is disposed adjacent to the logic circuit block LB or the power supply circuit block PB (data transfer destination) along the direction D1. When the control circuit block 202 of the programmable ROM 20 is disposed adjacent to the logic circuit block LB or the power supply circuit block PB (data transfer destination) along the direction D1, data can be supplied along a shorter path.

4. Electronic Instrument

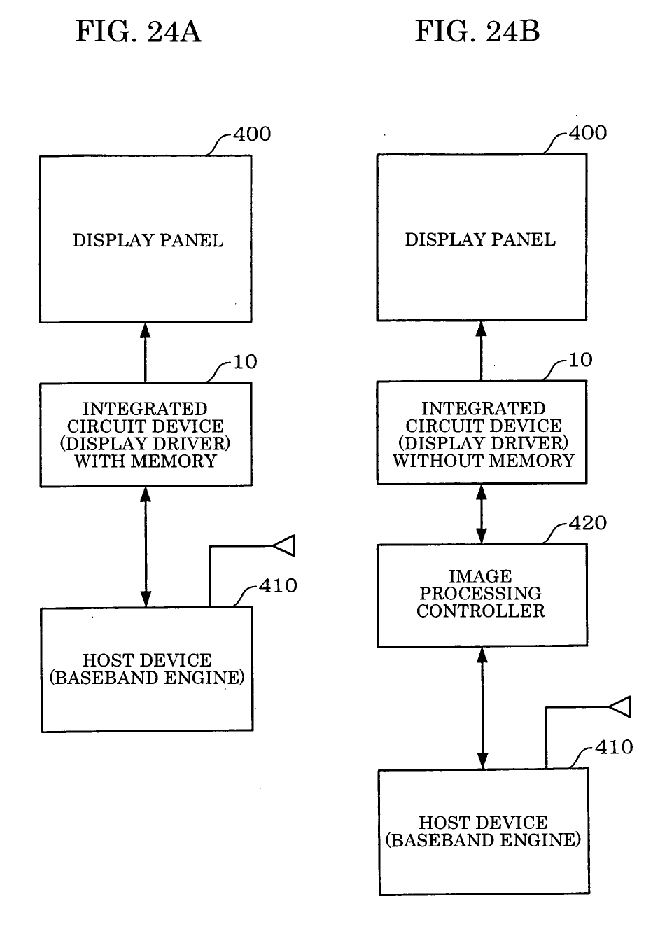

FIGS. 24A and 24B illustrate examples of an electronic instrument (electro-optical device) including the integrated circuit device 10 according to the above embodiment. The electronic instrument may include elements (e.g. camera, operation section, or power supply) other than the elements shown in FIGS. 24A and 24B. The electronic instrument according to this embodiment is not limited to a portable telephone, but may be a digital camera, PDA, electronic notebook, electronic dictionary, projector, rear-projection television, portable information terminal, or the like.

In FIGS. 24A and 24B, a host device 410 is a microprocessor unit (MPU), a baseband engine (baseband processor), or the like. The host device 410 controls the integrated circuit device 10 as a display driver. The host device 410 may also perform processing of an application engine or a baseband engine, or processing of a graphic engine such as compression, decompression, and sizing. An image processing controller (display controller) 420 shown in FIG. 24B performs processing of a graphic engine, such as compression, decompression, or sizing, instead of the host device 410.

A display panel 400 includes a plurality of data lines (source lines), a plurality of scan lines (gate lines), and a plurality of pixels specified by the data lines and the scan lines. The display operation is realized by changing the optical properties of an electro-optical element (liquid crystal element in a narrow sense) in each pixel region. The display panel 400 may be formed of an active matrix type panel using a switching element such as a TFT or TFD. The display panel 400 may be a panel other than an active matrix type panel, or may be a panel other than a liquid crystal panel.

In FIG. 24A, an integrated circuit device including a memory may be used as the integrated circuit device 10. In this case, the integrated circuit device 10 writes image data from the host device 410 into the built-in memory, and reads the written image data from the built-in memory to drive the display panel. In FIG. 24B, an integrated circuit device which does not include a memory may be used as the integrated circuit device 10. In this case, image data from the host device 410 is written into a memory provided in the image processing controller 420. The integrated circuit device 10 drives the display panel 400 under control of the image processing controller 420.

Although only some embodiments of the invention have been described in detail above, those skilled in the art would readily appreciate that many modifications are possible in the embodiments without materially departing from the novel teachings and advantages of the invention. Accordingly, such modifications are intended to be included within the scope of the invention. Any term (e.g. output-side I/F region and input-side I/F region) cited with a different term (e.g. first interface region and second interface region) having a broader meaning or the same meaning at least once in the specification and the drawings can be replaced by the different term in any place in the specification and the drawings. The configuration, arrangement, and operation of the integrated circuit device and the electronic instrument are not limited to those described in the above embodiments. Various modifications and variations may be made.

In the invention, the first conductivity type of the semiconductor substrate on which the programmable ROM is provided may be an N-type.

Although only some embodiments of the invention are described in detail above, those skilled in the art would readily appreciate that many modifications are possible in the embodiments without materially departing from the novel teachings and advantages of the invention. Accordingly, such modifications are intended to be included within the scope of the invention.

What is claimed is:

1. An integrated circuit device comprising:
a programmable ROM block including a plurality of memory cells, each of the memory cells including:
a write/read transistor and an erase transistor formed on a semiconductor substrate;
a floating gate which is used in common as gates of the write/read transistor and the erase transistor; and
a control gate which is formed in the semiconductor substrate and formed of an impurity region provided at a position opposite to the floating gate through an insulating layer;
when the semiconductor substrate is a first conductivity type, each of the memory cells having a triple-well structure formed by a deep well of a second conductivity type formed in the semiconductor substrate, a shallow well of the first conductivity type formed in the deep well of the second conductivity type, a ring-shaped shallow well of the second conductivity type which encloses the shallow well of the first conductivity type on the deep well of the second conductivity type, and top impurity regions formed in the shallow well of the first conductivity type and the ring-shaped shallow well of the second conductivity type; and
the erase transistor being formed in the ring-shaped shallow well of the second conductivity type, and the control gate and the write/read transistor being formed in the shallow well of the first conductivity type.

2. The integrated circuit device as defined in claim 1,
wherein the shallow well of the first conductivity type is separated from the ring-shaped shallow well of the second conductivity type, and the deep well of the second conductivity type is formed between the shallow well of the first conductivity type and the ring-shaped shallow well of the second conductivity type.

3. The integrated circuit device as defined in claim 1, further comprising:
a transfer gate including a transistor of the first conductivity type and a transistor of the second conductivity type between the write/read transistor and a bitline.

4. The integrated circuit device as defined in claim 3,
wherein the transistor of the second conductivity type is formed in the shallow well of the first conductivity type.

5. The integrated circuit device as defined in claim 4,
wherein the ring-shaped shallow well of the second conductivity type includes two long side regions;
wherein the erase transistor is formed in one of the two long side regions;
wherein a beltlike shallow well of the second conductivity type is formed adjacent to the other of the two long side regions; and
wherein the transistor of the first conductivity type is formed in the beltlike shallow well of the second conductivity type.

6. The integrated circuit device as defined in claim 5,
wherein the other of the two long side regions is separated from the beltlike shallow well of the second conductivity type, and a ring-shaped deep well of the first conductivity type is formed in a region around the ring-shaped shallow well of the second conductivity type and the beltlike shallow well of the second conductivity type.

7. The integrated circuit device as defined in claim 6,
wherein an impurity ring of the first conductivity type is formed in a top layer in a region in which the ring-shaped deep well of the first conductivity type is formed.

8. The integrated circuit device as defined in claim 5,
wherein the other of the two long side regions is separated from the beltlike shallow well of the second conductivity type, a ring-shaped shallow well of the first conductivity type is formed in a region which encloses the beltlike shallow well of the second conductivity type, and the ring-shaped shallow well of the first conductivity type is separated from the other of the two long side regions.

9. The integrated circuit device as defined in claim 8,
wherein an impurity ring of the first conductivity type is formed in a top layer of the ring-shaped shallow well of the first conductivity type.

10. The integrated circuit device as defined in claim 9,
wherein a first metal layer or a lower interconnect layer is not formed to extend over the impurity ring of the first conductivity type.

11. The integrated circuit device as defined in claim 5,
wherein a memory cell array block in which the memory cells are arranged is divided into first and second regions on either side of a center region, and includes two wordline drivers which respectively drive wordlines of the memory cells disposed in the first and second regions, and two control gate drivers which respectively drive the control gates of the memory cells disposed in the first and second regions.

12. The integrated circuit device as defined in claim 11,
wherein the memory cell array block includes a plurality of column blocks divided in a direction in which the wordlines extend;
wherein each of the wordlines is hierarchized into a main-wordline and a plurality of sub-wordlines subordinate to the main-wordline, and each of the sub-wordlines is disposed in units of the column blocks;
wherein each of the two wordline drivers is a main-wordline driver; and
wherein each of the column blocks includes a memory cell region and a sub-wordline decoder region divided in a direction in which the wordlines extend, and a sub-wordline decoder which selectively drives one of the sub-wordlines subordinate to the main-wordline based on logic of the main-wordline is disposed in the sub-wordline decoder region.

13. The integrated circuit device as defined in claim 12,
wherein the memory cell region and the sub-wordline decoder region are formed in a common well region formed on the semiconductor substrate.

14. The integrated circuit device as defined in claim 13,
wherein transistors forming the sub-wordline decoder disposed in the sub-wordline decoder region are formed in the shallow well of the first conductivity type and the beltlike shallow well of the second conductivity type.

15. The integrated circuit device as defined in claim 1,
wherein the first conductivity type is a P-type, and the second conductivity type is an N-type.

16. An electronic instrument comprising:
the integrated circuit device as defined in claim 1; and
a display panel driven by the integrated circuit device.
